(19) United States
(12) Patent Application Publication
(10) Pub. No.: US 2018/0309006 A1
(43) Pub. Date: Oct. 25, 2018

(54) Solar cell, preparation method thereof and solar cell module assembled thereof

(71) Applicant: Beijing Chuangyu Technology Co., Ltd, Beijing (CN)

(72) Inventor: Liguang LAN, Beijing (CN)

(73) Assignee: Beijing Chuangyu Technology Co., Ltd, Beijing (CN)

(21) Appl. No.: 15/769,074

(22) PCT Filed: Oct. 13, 2016
(86) PCT No.: PCT/CN2016/101975

§ 371 Date: Apr. 18, 2018

(30) Foreign Application Priority Data
Oct. 19, 2015 (CN) 201510679909.9

(51) Int. Cl. H01L 31/05; H01L 31/0216; H01L 31/0224; H01L 31/18

(52) U.S. Cl. CPC H01L 31/05; H01L 31/1868; H01L 31/022433; H01L 31/02168

(57) ABSTRACT

A solar cell comprises a window layer (4), a base layer (5), an emitter layer (6) and a passivation layer (8) provided in a stacking manner, an N type contact (12) array and a P type contact (13) array which are arranged at intervals on the solar cell, the N type contact penetrates through the emitter layer and the passivation layer, and the P type contact penetrates through the passivation layer; and cross sectional areas of open ends of the N type contacts are larger than its bottom cross sectional areas.

### RELATED APPLICATIONS

The present invention claims priority of Chinese Patent Application No. 201510679909.9, filed on Oct. 19, 2015 and named after “Solar cell, preparation method thereof and solar cell module assembled thereof”, the contents of which are hereby incorporated as a reference.

### TECHNICAL FIELD

The present invention relates to the technical field of solar cells, and more specifically to a solar cell and a solar module with such solar cells connected in series. The present invention also relates to a preparation method for the solar cell.

### BACKGROUND

Solar energy is an inexhaustible energy source. It is estimated that solar energy irradiating onto the earth in a year is equivalent to heat generated by 1,370 billion tons of standard coal, and is about more than twenty thousand times energy generated by various energy sources In a year throughout the world at present. In China, solar resources can be utilized better in about ⅔ of regions, solar energy generation is free of regional limits, and a photovoltaic system can be modularized, can be mounted in a place close to power consumption as well as a region far away from a power grid, so that power transmission and power distribution cost can be reduced, and reliability of a power supply facility can be improved. At present, a small amount of material is used for a light absorption layer of a thin film solar cell, so that only a few microns are required by effective conversion of solar energy into electric energy by its inherent material property.

A semiconductor heterojunction solar cell is formed by two semiconductor materials with different energy band structures, energy bands can be bent or mutated on a contact interface, thereby forming a built-in electric field, to provide a condition for separating carriers generated by a photovoltaic effect in a semiconductor. Since there are various semiconductor materials, there are also multiple materials selected to form heterojunction solar cells. At present, semiconductor heterojunction solar cells mainly include amorphous silicon/monocrystalline silicon heterojunction cells, Indium Gallium Phosphide (InGaP)/Gallium Arsenide (GaAs) heterojunction cells, Cadmium Sulfide (CdS)/Cadmium Telluride (CdTe) heterojunction cells, organism heterojunction and Aluminum Gallium Arsenide (AlGaAs)/GaAs heterojunction cells and the like. An Epitaxial Lift-Off (ELO) technology implemented by a HydroFluoric (HF) acid is used to separate a GaAs epitaxial layer from a substrate, and a p-n layer is formed by contact between an n type doped base layer and a p+ type doped emitter layer. When light is absorbed near the p-n layer to generate electron-hole pairs, a built-in electric field in a heterojunction to drive holes to a p+ type doped side and move electrons to an n type doped side. Displacement of a photon-generated carrier forms an electric potential difference between the p+ type doping side and the n type doping side to achieve the photovoltaic effect. A GaAs thin film solar cell is a cell with highest photoelectric conversion efficiency in present thin film cells, has the characteristics of lightweight, flexibility and the like, has broad application prospect, may have high output power under a smaller illuminated area under the same condition due to its characteristic of high efficiency, and may be applied to a consumer solar product.

At present, a Metal Organic Chemical Vapor Deposition (MOCVD) method is mainly adopted to deposit cell layers on GaAs substrates to form photovoltaic devices, then an ELO technology is adopted to lift off the cell layers, N type electrode contacts are interconnected and P+ type electrode contacts are interconnected of a photovoltaic device to form a photovoltaic conversion module with higher current output, or the N type contacts and P type contacts are interconnected to form a photovoltaic conversion module with a higher output voltage. However, in a preparation process for a back contact type GaAs cell, a dry or a wet etching is required to anisotropically etch cylindrical grooves to further prepare contacts. Sidewall of the cylindrical grooves are perpendicular to the cell, and this is unfavorable for depositing and attaching a passivator to the sidewall of the cylindrical grooves in a subsequent passivation layer preparation process, so that it probably causes the problems of cavities, excessively small and nonuniform thicknesses of passivation layers attached to the sidewalls and the like, and the problem of anode and cathode short-circuit in an electrode contact preparation process is also easily brought. In addition, for achieving proper thicknesses of the passivation layers on the sidewalls of the cylindrical grooves, a longer time is required by cell surface passivation, so that a process time and the amount of a raw material used are increased. Moreover, excessive exposition of GaAs material layers increases a dark current, and for avoiding contact between base electrodes and P type AlGaAs, larger base electrode grooves are required, which further increases the dark current. Therefore, smaller base electrode grooves are required, but the smaller electrode grooves make it difficult to prepare the passivation layers on sidewalls of the grooves and difficult to prepare the base electrodes.

### SUMMARY

To this end, the technical problem to be solved by the present invention is the problem that it is difficult to form a passivation layer on a sidewall due to the fact that an N type contact of an existing solar cell is cylindrical, and a solar cell and a solar cell module with such solar cells connected in series are further provided. A shape of the N type contact of the solar cell is changed to solve the problem that it is difficult to form the passivation layer on the sidewall, lower the process difficulty and reduce use of a passivation material.

The following technical solutions are adopted.

A solar cell comprises a window layer, a base layer, an emitter layer and a passivation layer which are provided in a stacking manner, wherein the solar cell further comprises an N type contact array and a P type contact arrays which is arranged at intervals, The N type contact penetrates through the emitter layer and the passivation layer, and the P type contact penetrates through the passivation layer, and

the solar cell further comprises an interface layer provided between the emitter layer and the passivation layer, the N type contact penetrates through the emitter layer, the interface layer and the passivation layer to expose the base layer, and the P type contact penetrates through the passivation layer to expose the interface layer.

A cross sectional area of open end of the N type contact is larger than its bottom cross sectional area.

The N type contact is inverted circular truncated cone-shaped.

An acute angle α formed by a sidewall of the N type contact and a horizontal plane are: 5°≤α≤85.

A sidewall passivation layer formed by extension of the passivation layer is provided on outer side of the sidewall of the N type contact.

Adjacent the N type contact array and the P type contact array form a contact array group, the number of the contact array groups is an even number, and the N type contact array and the P type contact array of the contact array group arranged on one side of a centerline of the solar cell form a mirror distribution with the P type contact array and the N type contact array of the contact array group on the other side of the centerline respectively.

Adjacent the N type contact array and the P type contact array form a contact array group, the number of the contact array groups is an odd number, and the N type contact array and the P type contact array arranged on one side of a centerline of the middle contact array group form a mirror distribution with the P type contact array and the N type contact array of the contact array group on the other side of the centerline respectively.

The N type contact arrays and the P type contact arrays are arranged at equal interval.

The solar cell is a gallium arsenide thin film solar cell.

The solar cell further comprises an Anti-Reflection coating provided on a side of the window layer, which the side is far away from the base layer.

A series-connected solar module comprises at least two solar cells, and an N type contact array and a P type contact array at corresponding positions of adjacent solar cells are serially electrically conducted.

The N type contact array and P type contact array at the corresponding positions of the adjacent solar cells are electrically conducted to be connected in series through an electrode connecting wires.

Each solar cell is arranged reversely in parallel with the adjacent solar cell.

Wherein, being arranged reversely in parallel refers to that the adjacent solar cell of the solar cell is obtained by rotating the solar cell 180°, two ends of the two cells may be aligned, and the two ends of the two cells may also not be aligned.

The N type contact array of the solar cell is electrically conducted with the P type contact array of the adjacent solar cell through an electrode connecting wire, and the P type contact array is electrically conducted with the N type contact array of the adjacent solar cell through an electrode connecting wire.

A preparation method of a solar cell comprises the following steps:

S1: a buffer layer, a release layer, a window layer, a base layer, an emitter layer and an interface layer are sequentially prepared on a substrate;

S2: inverted circular truncated cone-shaped grooves distributed in arrays penetrating through the interface layer and the emitter layer are formed in an etching manner, the base layer being at bottom of the inverted circular truncated cone-shaped groove an acute angle α formed by sidewall and a horizontal plane of the inverted circular truncated cone-shaped groove is: 5°≤α≤85°;

S3: a passivation layer is prepared on the basis of Step S2, an area reserved for an N type contact in the inverted circular truncated cone-shaped groove is covered by masking process, thereby forming a passivation layer on the interface layer and forming a sidewall passivation layer on the sidewall of the inverted circular truncated cone-shaped groove, and an inverted circular truncated cone-shaped base electrode groove is formed between the sidewall passivation layers and the base layer;

S4: an emitter electrode groove distributed in array penetrating through the passivation layer is formed in the etching manner, the interface layer is at bottom of the emitter electrode groove;

S5: the N type contacts is prepared in the inverted circular truncated cone-shaped base electrode groove, and the P type contact is prepared in the emitter electrode groove; and

S6: the substrate, the buffer layer and the release layer are lifted off, to obtain the solar cell.

Preferably, Step S2 is: the inverted circular truncated cone-shaped groove etched by a dry etching or a wet isotropic etching;

Step S4 is: the emitter electrode groove is etched by a dry etching or a wet etching and

Step S6 is: after the substrate, the buffer layer and the release layer are lifted off, an Anti-Reflection coating is provided on a side of the window layer, which the side is far away from the base layer,

Alternately, Step S3 is: the passivation layer is formed on the interface layer, the sidewall passivation layer is formed on the sidewall of the inverted circular truncated cone-shaped groove, then the passivation layer at the bottom of the inverted circular truncated cone-shaped groove is removed by an etching process to expose the base layer for preparation of a base electrode, and the inverted circular truncated cone-shaped base electrode groove is formed between the sidewall passivation layers and the base layer.

Compared with a conventional art, the present invention has the following beneficial effects:

A purpose of the present invention is to provide a novel solar cell. The solar cell comprises the P type contact array and the N type contact array arranged at intervals, the N type contact is inverted circular truncated cone-shaped, and an acute angle α formed by the sidewall of the N type contact and the horizontal plane is: 5°≤α≤85°. Inner sidewall surfaces of the inverted circular truncated cone-shaped grooves form certain inclination angles with the base layer, so that difficulties in preparation of the sidewall passivation layer can be remarkably lowered. Meanwhile, implementing the inverted circular truncated cone-shaped base electrode prepared method may reduce surface defects caused by preparation of the base electrode groove, reduce a dark current of the cell and improve efficiency of the cell.

Furthermore, each solar cell of the present invention has the same structure, and during connection, the electrode contact (the P type contact) of the solar cell is connected with different contact (the N type contact) of an adjacent solar cell, and its N type contact connected with different contact (the P type contacts) of the adjacent solar cell, thereby forming series connections of GaAs photovoltaic devices. Such a preparation method avoids preparation of GaAs photovoltaic device units with two types of electrode contact layouts, and has the characteristics of simple structure and easiness for implementation.

### BRIEF DESCRIPTION OF THE DRAWINGS

For making it easier to comprehend the contents of the present invention clearly, the present invention will further be described below according to specific embodiments of the present invention and in combination with the drawings in detail, wherein

FIG. 1 is a structure diagram of a solar cell according to the present invention;

FIG. 2 is a partial enlarged drawing of a part I in FIG. 1;

FIG. 3 is a partial enlarged drawing of a part II in FIG. 1;

FIG. 4 is a structure diagram of a solar cell;

FIG. 5 is a structure diagram of another embodiment of a solar cell;

FIG. 6 is a structure diagram of a placement manner for a solar module;

FIG. 7 is an A-A sectional view of FIG. 6;

FIG. 8 is a partial enlarged drawing of a part I of FIG. 7;

FIG. 9 is a partial enlarged drawing of a part II of FIG. 7; and

FIG. 10 is a schematic diagram of a preparation process for a solar cell.

In the drawings: 1-substrate; 2-buffer layer; 3-release layer; 4-window layer; 5-base layer; 6-emitter layer; 7-interface layer; 8-passivation layer; 10-sidewall passivation layer; 12-N type contact; 13-P type contact; 14-electrode connecting wire; and 15-Anti-Reflection coating.

### DETAILED DESCRIPTION OF THE EMBODIMENTS

For making the purpose, technical solutions and advantages of the present invention more clearly, embodiments of the present invention will further be described below in combination with the drawings in detail.

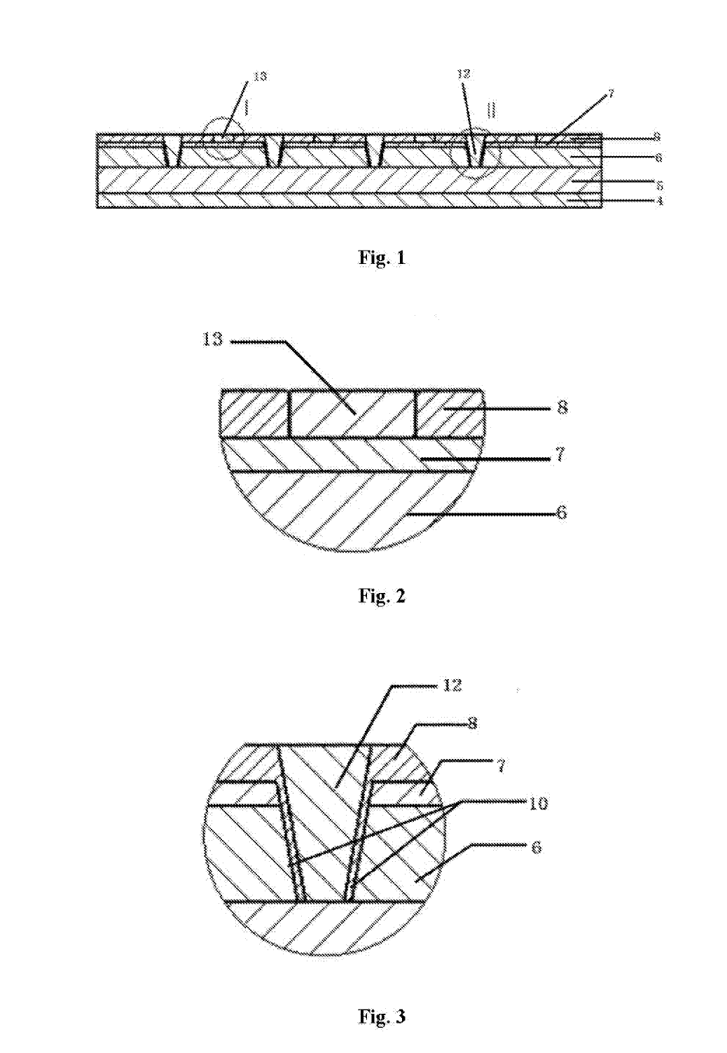

As shown in FIG. 1-3, a solar cell of the present invention comprises a window layer 4, a base layer 5, an emitter layer 6 and a passivation layer 8, the solar cell further comprises an N type contact 12 array and a P type contact 13 array which are arranged at intervals, the N type contact 12 penetrates through the emitter layer 6 and the passivation layer 8, and the P type contact 13 penetrates through the passivation layer 8.

As another embodiment, the solar cell further comprises an interface layer 7 provided between the emitter layer 6 and the passivation layer 8, the N type contact 12 penetrates through the emitter layer 6, the interface layer 7 and the passivation layer 8 to expose the base layer 5, and the P type contact 13 penetrates through the passivation layer 8 to expose the interface layer 7.

A cross sectional area of open end of the N type contact 12 is larger than its bottom cross sectional area of the N type contact 12, the N type contact is preferably inverted circular truncated cone-shaped, an acute angle α formed by sidewall of the N type contact 12 and a horizontal plane is: 5°≤α≤85. A sidewall passivation layer 10 formed by extension of the passivation layer 8 is provided on outer side of the sidewall of the N type contact 12.

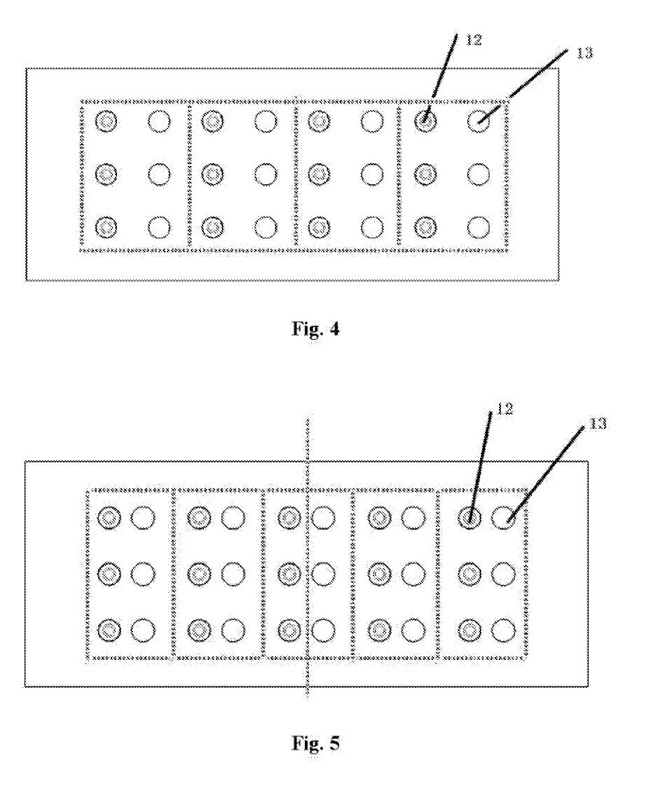

Furthermore, as shown in FIG. 4, adjacent the N type contact 12 array and the P type contact 13 array form a contact array group (shown in dashed boxes in the figure), and the number of the contact array groups can be an even number and can also be an odd number. In FIG. 4, the number of the contact array groups is an even number, and the N type contact 12 array and the P type contact 13 array of the contact array group arranged on one side of a centerline of the solar cell form a mirror distribution with the P type contact 13 array and N type contact 12 array of the contact array group on the other side of the centerline respectively. Specifically, the centerline of the solar cell in FIG. 4 refers to a dashed line between the second contact array group and the third contact array group, the N type contact 12 array of the first contact array group forms a mirror distribution with the P type contact 13 array of the fourth contact array group, and the P type contact 13 array of the first contact array group forms a mirror distribution with the N type contact 12 array of the fourth contact array group; and the N type contact 12 array of the second contact array group forms a mirror distribution with the P type contact 13 array of the third contact array, and the P type contact 13 array of the second contact array group forms a mirror distribution with the N type contact 12 array of the third contact array group.

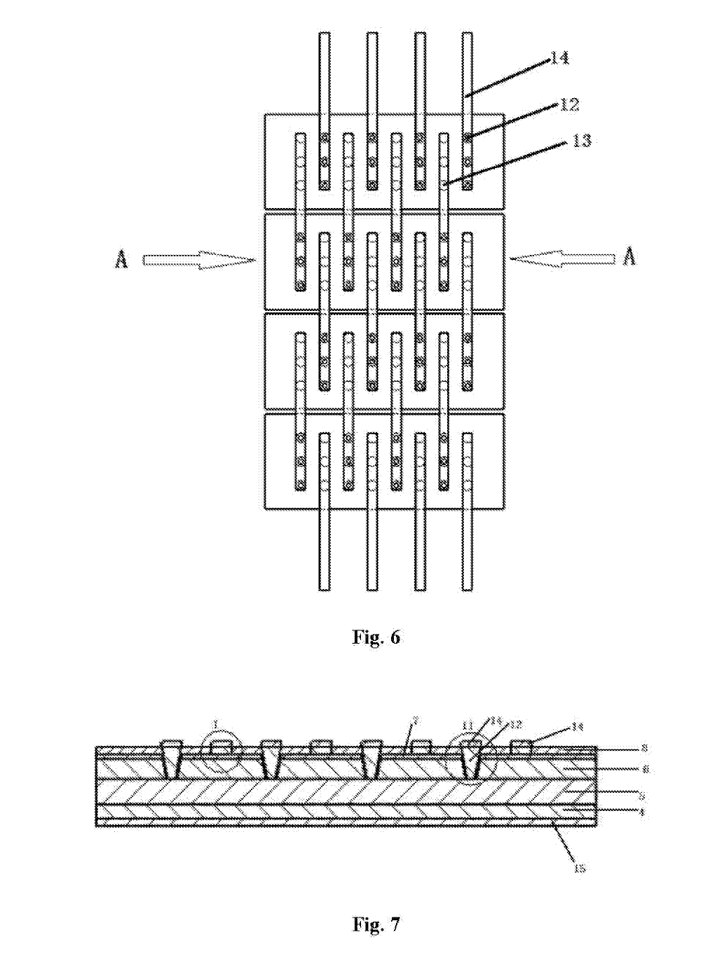

The number of the contact array groups shown in FIG. 5 is an odd number, and the N type contact array and the P type contact array arranged on one side of a centerline of the middle contact array group form a mirror distribution with the P type contact array and N type contact array of the contact array group on the other side of the centerline respectively. Specifically, the N type contact 12 array of the first contact array group forms a mirror distribution with the P type contact 13 array of the fifth contact array group, and the P type contact 13 array of the first contact array group forms a mirror distribution with the N type contact 12 array of the fifth contact array group; and the N type contact 12 array of the second contact array group forms a mirror distribution with the P type contact 13 array of the fourth contact array group, the P type contact 13 array of the second contact array group forms a mirror distribution with the N type contact 12 array of the fourth contact array group, and the N type contact 12 array and P type contact 13 array of the third contact array group form a mirror distribution.

The N type contact 12 arrays and the P type contact 13 arrays can be arranged at unequal interval, may also be arranged at equal interval, and are preferably arranged at equal interval.

The solar cell of the present invention is a gallium arsenide thin film solar cell.

A series-connected solar cell module of the present invention comprises at least two solar cells shown In FIG. 4, and an N type contact 12 array and a P type contact 13 array at corresponding positions of adjacent solar cells are electrically conducted to be connected in series. FIG. 6 is a series connection diagram of four solar cells shown in FIG. 4.

As a preferred embodiment, the N type contact 12 array and P type contact 13 array at the corresponding positions of the adjacent solar cell are electrically conducted to be connected in series through an electrode connecting wire 14.

Specifically, the N type contact 12 array of the solar cell is electrically conducted with the P type contact 13 array of the adjacent solar cell through the electrode connecting wire 14, and the P type contact 13 array is electrically conducted with the N type contact 12 array of the adjacent solar cell through the electrode connecting wire 14.

As shown in FIG. 6, the series-connected solar cell module comprises four solar cells which are structurally identical, the solar cells are sequentially numbered to be a first solar cell, a second solar cell, a third solar cell and a fourth solar cell from top to bottom, and of course, more solar cells may further be comprised according to a requirement. For making the structure neater and using fewest the electrode connecting wires 14, when the solar cells are connected in series, the solar cells forming the solar module in even lines are the same placement manner, the solar cells forming the solar module in odd lines are the same placement manner, and compared with the solar cells in the odd lines, placement positions of the solar cells in the even lines are rotated 180°.

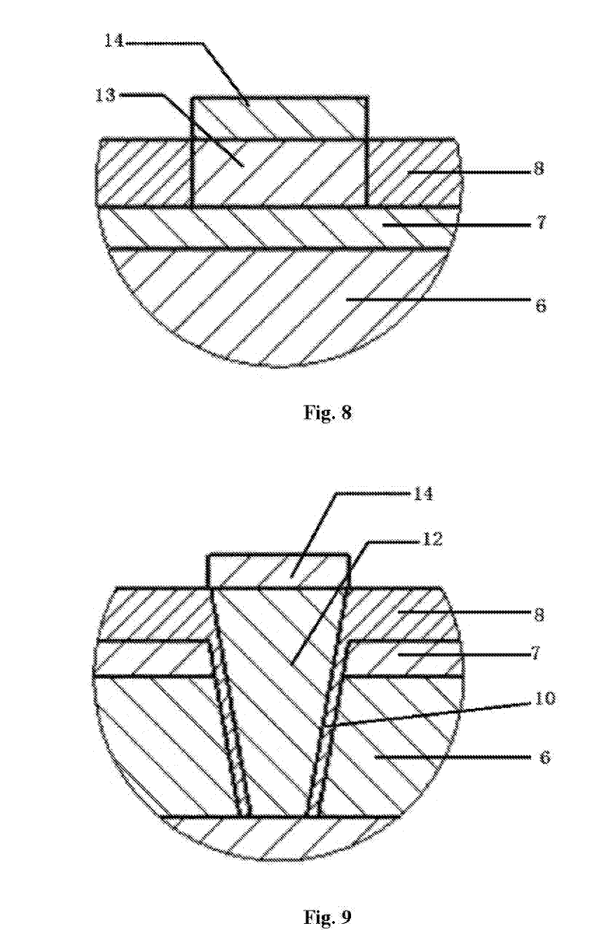

As shown in FIG. 6 to FIG. 9, each solar cell is arranged reversely in parallel with the adjacent solar cell, the N type contact 12 array of the solar cell is electrically conducted with the P type contact 13 array of the adjacent solar cell through the electrode connecting wire 14, and the P type contact 13 array is electrically conducted with the N type contact 12 array of the adjacent solar cell through the electrode connecting wire 14. Specifically, the first solar cell and the third solar cell are the same placement manner, the second solar cell and the fourth solar cell are the same placement manner, and after the first solar cell is placed, the second solar cell is rotated 180° to be arranged in parallel with the first solar cell with two ends aligned, and at this moment, the first solar cell and the second solar cell form a reverse parallel arrangement. At this moment, the N type contact 12 array of the first solar cell and the P type contact 13 array of the second solar cell are positioned in the same straight line, the P type contact 13 array of the first solar cell and the N type contact 12 array of the second solar cell are positioned in the same straight line, and the two are connected through the electrode connecting wires 14 respectively to implement series connection between the first solar cell and the second solar cell. The same connection manner is adopted for the third solar cell and the fourth solar cell until all the solar cells are connected in series.

Unless otherwise noted, the N type contact 12 array of the present invention refers to a column (or a row) formed by several N type contacts 12, and the P type contact 13 array refers to a column (or a row) formed by several P type contacts 13.

A preparation method for the solar cell comprises the following steps.

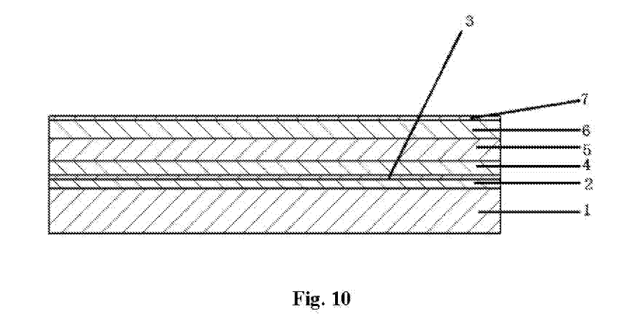

S1, as shown in FIG. 10, a buffer layer 2 is deposited on a substrate 1: the GaAs buffer layer 2 is deposited on the GaAs substrate 1 by a Metal Organic Chemical Vapor Deposition technology, wherein a structure of the buffer layer 2 can be a single-layer or multilayer structure, a function of the buffer layer is to provide an intermediate layer between the GaAs substrate 1 and a final photoelectric conversion unit, thereby reducing defect center and lattice stress influence caused by lattice mismatch when each epitaxial layer is formed to epitaxialy grow epitaxial layers with various lattice structures, and for example, a GaAs buffer layer 2 with a thickness of about 150 nm-250 nm can be applied to photovoltaic cells with various GaAs doped structures;

deposition of an Aluminum Arsenide (AlAs) release layer 3: deposition of the AlAs release layer 3 is performed on the GaAs buffer layer 2, wherein the release layer 3 comprising, but not limited to, an AlAs epitaxial material, the thickness range of release layer 3 is 5 nm-15 nm, such a thin release layer 3 is mainly used as a sacrificial layer, and an HF acid wet etching technology can be adopted, thereby separating the epitaxial layers subsequently deposited on the release layer from the buffer layer 2 and the GaAs substrate 1;

a window layer 4 deposition process: an AlGaAs semiconductor layer with a thickness of 10 nm-40 nm is deposited on the AlAs release layer 3 by an MOCVD method, wherein a proportion of Al:Ga is between 0.2:0.8 and 0.3:0.7, and the transparent window layer allows photons to directly penetrate through without absorption;

a base layer 5 deposition process: an n type III-V family compound material GaAs is deposited on the window layer 4, wherein the base layer 5, i.e., a GaAs layer, can be a single-crystal structure and can also be an n type doping material, wherein a doping concentration of an n type doped base layer 5 can range from 1×10¹⁶ cm⁻³ to 1×10¹⁹ cm⁻³, for example, 5×10¹⁷ cm⁻³, and a thickness of the base layer ranges from 400 nm to 4,000 nm;

an emitter layer 6 preparation process the emitter layer 6 is prepared on the base layer 5 by the MOCVD method, wherein the emitter layer 6 comprises any proper III-V family compound semiconductor capable of forming a heterojunction structure with the base layer 5, and for example, if the base layer is a GaAs material, the emitter layer 6 is an AlGaAs layer and is P type heavily doped with a doping concentration ranging from 1×10¹⁷ cm⁻³ to 1×10²⁰ cm⁻³, for example, 5×10¹⁸ cm⁻³, a thickness of the emitter layer is between 150 nm and 450 nm, for example, 300 nm, and then the base layer 5 and the emitter layer 6 form a photoelectric absorption layer; and

an interface layer 7 preparation process: the interface layer 7 is prepared on the emitter layer 6 by the MOVCD method, wherein the interface layer 7 and the emitter layer are both AlGaAs layers, the interface layer 7 is P+ type heavily doped with a doping concentration ranging from 5×10¹⁷ cm⁻³ to 5×10² cm⁻³, for example, 1×10¹⁹ cm⁻³, a purpose of P+ type heavy doped can facilitate the formation of ohmic contact, and a thickness of the interface layer 7 is between 100 nm and 400 nm, for example, 200 nm.

In S2, inverted circular truncated cone-shaped grooves are prepared: inverted circular truncated cone-shaped grooves distributed in arrays penetrating through the interface layer 7 and the emitter layer 6 are etched by a dry etching or a wet isotropic etching, the base layer 5 is at bottom of the inverted circular truncated cone-shaped groove, an acute angles α formed by sidewall of the inverted circular truncated cone-shaped groove and a horizontal plane is: 5°≤α≤85°.

In S3, a passivation layer 8 preparation process: any proper passivation process can be adopted, for example, a Chemical Vapor Deposition (CVD) or plasma-enhanced chemical vapor deposited, an area reserved for N type contacts 12 in the inverted circular truncated cone-shaped groove is covered by a masking process, thereby forming the passivation layer 8 on the interface layer 7 and forming a sidewall passivation layer 10 on the sidewall of the inverted circular truncated cone-shaped groove, wherein the passivation layer 8 and the sidewall passivation layer 10 can comprise any nonconductive material, including, but not limited to, one or stacked structure of more of Silicon Nitride (SINx), Oxide Silicon (SiOx), Titanium Oxide (TiOx), Thallium Oxide (TaOx) and Zinc Sulfice (ZnS); and inverted circular truncated cone-shaped base electrode groove is formed between the sidewall passivation layers 10 and the base layer 5.

The passivation layer 8 can also be formed on the interface layer 7, the sidewall passivation layer 10 is formed on the sidewalls of the inverted circular truncated cone-shaped groove, and then the passivation layer at the bottom of the inverted circular truncated cone-shaped groove is removed by an etching process to expose the base layer 5 to form the inverted circular truncated cone-shaped base electrode groove.

In S4, emitter electrode grooves distributed in arrays penetrating through the passivation layer 8 are etched by a dry etching or a wet etching, the interface layer 7 is at bottom of the emitter electrode groove, a region of the P type contact 13 is reserved in the emitter electrode groove, the number of columns of the emitter electrode grooves along an X direction is the same with the number of columns of the inverted circular truncated cone-shaped base electrode grooves, and meanwhile, the emitter electrode grooves and the inverted circular truncated cone-shaped base electrode grooves are alternately distributed.

In S5, electrode contacts preparation: the N type contact 12 is prepared in the inverted circular truncated cone-shaped base electrode groove, and the P type contact 13 is prepared in the emitter electrode groove. The N type contact 12 and the P type contact 13 can be proper metal or metal alloy conducting materials and should not pierce the semiconductor layer of a photoelectric device during preparation. In addition, the material of the N type contact may preferably be applicable at a relatively low metallization process temperature (for example, between 150° C. and 200° C.). For example, Palladium (Pd) don't react with GaAs, so that the N type contact 12 and the P type contact 13 can be formed by a Palladium/Germanium (Pd/Ge) alloy. Therefore, GaAs photovoltaic device units may be formed. A preparation method of the N type contact 12 and the P type contact 13 comprises, but not limited to, a vacuum evaporation, a photoresist, a photolithography, a screen printing and a sputtering, so that deposition is performed only at the positions of the N type contact 12 and the P type contact 13. These methods all involve the same system, wherein a part requiring no contacts is protected.

In S6, an epitaxial lift off process of GaAs photovoltaic device units: each epitaxial layer subsequently deposited on the release layer is separated from the buffer layer 2 and the GaAs substrate 1 by a HF acid wet etching technology, result in lifting off and forming the GaAs photovoltaic device units. An Anti-Reflection coating 15 is configured on the window layer 4, and the Anti-Reflection coating comprises any material allowing light to pass through and prevent the light from being reflected on its surface, including one or any combination of Magnesium Fluoride (MgF₂), Silicon Dioxide (SiO₂), Zinc Sulfice (ZnS), Titanium Dioxide (TiO₂) and Silicon Nitride (SiN). Any proper method (for example, the sputtering method) may be adopted to coat the Anti-Reflection coating on the window layer 4. In addition, pre coating Anti-Reflection coating, the window layer 4 can be roughened or texturized by a wet etching or a dry etching. The window layer 4 can be roughened or texturized to provide different angles at an interface between the Anti-Reflection coating and the window layer 4 (these layers with different refractive indexes), then the incident angle of some photons is excessively high according to the Snell's Law, as a result more incident photons can be transmitted into the window layer 4 rather than being reflected at the interface between the Anti-Reflection coating and the window layer 4, so that transmittance of the photons is improved.

Obviously, the above mentioned embodiments are only examples listed for clear description and not intended to limit the implementation modes. Those of ordinary skilled in the art may further make variations or modifications in other different forms on the basis of the descriptions made above, and not all the implementation modes are required to be exhausted herein. Apparent variations or modifications derived therefrom still fall within the scope of protection of the present invention.

What is claimed is:

1. A solar cell, comprising a window layer (4), a base layer (5), an emitter layer (6) and a passivation layer (8) arranged in a stacking manner, wherein an N type contact (12) array and a P type contact (13) array which are arranged at intervals on the solar cell, the N type contact (12) penetrating through the emitter layer (6) and the passivation layer (8), and the P type contact (13) penetrating through the passivation layer (8),
wherein a cross sectional area of an open end of the N type contact (12) is larger than a bottom cross sectional area of the N type contact (12).

2. The solar cell as claimed in claim 1, wherein the solar cell further comprising an interface layer (7) arranged between the emitter layer (6) and the passivation layer (8), the N type contact (12) penetrating through the emitter layer (6), the interface layer (7) and the passivation layer (8) to expose the base layer (5), and the P type contact (13) penetrating through the passivation layer (8) to expose the interface layer (7).

3. (canceled)

4. The solar cell as claimed in claim 1, wherein the N type contact (12) is inverted circular truncated cone-shaped.

5. The solar cell as claimed in claim 4, wherein an acute angle α formed by a sidewall of the N type contact (12) and a horizontal plane is: 5°≤α≤85°.

6. The solar cell as claimed in claim 5, wherein a sidewall passivation layer (10) formed by extension of the passivation layer (8) is provided on outer side of the sidewall of the N type contact (12).

7. The solar cell as claimed in claim 6, wherein adjacent the N type contact (12) array and the P type contact (13) array form a contact array group, the number of the contact array groups is an even number, and the N type contact (12) array and the P type contact (13) array of the contact array group arranged on one side of a centerline of the solar cell form a mirror distribution with the P type contact (13) array and the N type contact (12) array of the contact array group on the other side of the centerline respectively.

8. The solar cell as claimed in claim 6, wherein adjacent the N type contact (12) array and the P type contact (13) array form a contact array group, the number of the contact array groups is an odd number, and the N type contact (12) array and the P type contact (13) array arranged on one side of a centerline of the middle contact array group form a mirror distribution with the P type contact (13) array and the N type contact (12) array of the contact array group on the other side of the centerline respectively.

9. The solar cell as claimed in claim 1, wherein the N type contact (12) array and the P type contact (13) array are arranged at equal interval.

10. The solar cell as claimed in claim 9, wherein the solar cell is a gallium arsenide thin film solar cell.

11. The solar cell as claimed in claim 1, wherein the solar cell further comprising an Anti-Reflection coating (15) arranged on a side of the window layer (4), which the side is far away from the base layer (5).

12. A series-connected solar cell module, comprising at least two solar cells as claimed in 1, wherein an N type contact (12) array and a P type contact (13) array at corresponding positions of adjacent solar cells are serially electrically conducted.

13. The series-connected solar cell module as claimed in claim 12, wherein each solar cell is arranged reversely in parallel with the adjacent solar cell.

14. The series-connected solar module as claimed in claim 12, wherein the N type contact (12) array of the solar cell is electrically connected with the P type contact (13) array of the adjacent solar cell through an electrode connecting wire (14), and the P type contact (13) array is electrically connected with the N type contact (12) array of the adjacent solar cell through an electrode connecting wire (14).

15. A preparation method of a solar cell, comprising the following steps:
S1: sequentially preparing a buffer layer (2), a release layer (3), a window layer (4), a base layer (5), an emitter layer (6) and an interface layer (7) on a substrate (1);
S2: forming inverted circular truncated cone-shaped grooves distributed in array penetrating through the interface layer (7) and the emitter layer (6) in an etching manner, the base layer (5) being at bottom of the inverted circular truncated cone-shaped groove, an acute angle α formed by a sidewall of the inverted circular truncated cone-shaped groove and a horizontal plane is: 5°≤α≤85°;
S3: preparing a passivation layer (8) on the basis of Step S2, covering an area reserved for an N type contact (12) in the inverted circular truncated cone-shaped groove by a masking process, thereby forming a passivation layer (8) on the interface layer (7) and forming a sidewall passivation layer (10) on the sidewall of the inverted circular truncated cone-shaped groove, and forming an inverted circular truncated cone-shaped base electrode groove between the sidewall passivation layers (10) and the base layer (5);
S4: forming an emitter electrode groove distributed in array penetrating through the passivation layer (8) in the etching manner, the interface layer (7) being at bottom of the emitter electrode groove;
S5: preparing the N type contact (12) in the inverted circular truncated cone-shaped base electrode groove, and preparing the P type contact (13) in the emitter electrode groove; and
S6: lifting off the substrate (1), the buffer layer (2) and the release layer (3), to obtain the solar cell.

16. The preparation method for the solar cell as claimed in claim 15, wherein
step S2 is: forming the inverted circular truncated cone-shaped groove by a dry etching or a wet isotropic etching; and
step S4 is: forming the emitter electrode groove by a dry etching or a wet etching.

17. The preparation method for the solar cell as claimed in claim 15, wherein
step S3 can also be: forming the passivation layer (8) on the interface layer (7), forming the sidewall passivation layer (10) on the sidewall of the inverted circular truncated cone-shaped groove, then removing the passivation layer at the bottom of the inverted circular truncated cone-shaped groove by an etching process to expose the base layer (5) for preparation of a base electrode, and forming the inverted truncated circular cone-shaped base electrode groove between the sidewall passivation layer (10) and the base layer (5).

18. The preparation method for the solar cell as claimed in 15, wherein Step S6 further comprises:
after lifting off the substrate (1), the buffer layer (2) and the release layer (3), preparing an Anti-Reflection coating (15) on a side of the window layer (4), which the side is far away from the base layer (5).

19. The solar cell as claimed in claim 2, wherein the N type contact (12) is inverted circular truncated cone-shaped.

20. The solar cell as claimed in claim 2 wherein the N type contact (12) arrays and the P type contact (13) arrays are arranged at equal interval.

21. The solar cell as claimed in claim 2, wherein the solar cell further comprising an Anti-Reflection coating (15) arranged on a side of the window layer (4), which the side is far away from the base layer (5).
